(19) United States
(12) Patent Application Publication
(10) Pub. No.: US 2008/0309429 A1
(43) Pub. Date: Dec. 18, 2008

(54) MONOLITHIC INTEGRATED INDUCTOR

(76) Inventor: Samir El Rai, Colorado Springs, CO (US)

Correspondence Address: Muncy, Geissler, Olds & Lowe, PLLC, P.O. BOX 1364, FAIRFAX, VA, 22038-1364, US

(21) Appl. No.: 12/138,408

(22) Filed: Jun. 12, 2008

Related U.S. Application Data
(60) Provisional application No. 60/944,090, filed on Jun. 14, 2007.

(30) Foreign Application Priority Data
Jun. 12, 2007 (DE) DE102007027 612.7

(51) Int. Cl. H03H 7/00; H01F 27/28; H01F 29/00

(52) U.S. Cl. 333/167; 336/180; 336/69

(57) ABSTRACT

A monolithic integrated inductor and a method for configuring the monolithic integrated inductor are provided. The monolithic integrated inductor includes a first coil having a first inductance value, at least one second coil connected in parallel to the first coil and having a second inductance value to form a total inductance, and lines to the first coil and to the second coil. The first coil has at least two first loops spaced at a distance with a path width. The second coil has at least two second loops spaced at the distance with the path width. The first loops form a magnetic coupling, and the second loops form a magnetic coupling.

This nonprovisional application claims priority to German Patent Application No. 10 2007 027 612.7, which was filed in Germany on Jun. 12, 2007 and to U.S. Provisional Application No. 60/944,090, which was filed on Jun. 14, 2007, and which are both herein incorporated by reference.

### BACKGROUND OF THE INVENTION

1. Field of the Invention

The present invention relates to a monolithic integrated inductor.

2. Description of the Background Art

An equivalent circuit for a coil for high-frequency applications is shown in FIG. 1. The coil has an inductance L. Line resistances and other losses of a high-frequency signal are represented by the resistance R_{L}(f), the resistance value being dependent on the frequency f of the high-frequency signal. The resistance R_{L}(f) depends on the skin resistance (skin effect) of the winding and is proportional to the root of the frequency f. The parasitic capacitor C_{L} acts parallel to the series connection including inductor L and resistor R_{L}(f. Inductor L, resistor R_{L}(f), and the parasitic capacitor C_{L} function as a damped parallel resonant circuit with the parallel resonance frequency

$${f}_{r} = \frac{1}{2 π \sqrt{{LC}_{L}}} \qquad ( 1 )$$

Diagrams showing the value of the impedance and the coil quality of SMD coils, size 1206, whose impedance |Z| and quality Q_{L} are shown schematically in FIGS. 2 and 3, are known from “Halbleiter-Schaltungstechnik” [Semiconductor Circuit Engineering], U. Tietze and Ch. Schenk, 12^{th} ed., 2002, page 1329.

### SUMMARY OF THE INVENTION

It is therefore an object of the present invention to increase the quality of a resonant circuit for high frequencies as much as possible.

Accordingly, the use of at least two monolithic integrated coils with a total inductance is provided to increase quality, instead of a monolithic integrated single coil with the same inductance. The at least two monolithic integrated coils are connected in parallel. Each of the two monolithic integrated coils has at least two preferably complete loops with magnetic coupling between the two loops.

Accordingly, a method for forming a monolithic integrated inductor is provided. The inductor is formed by parallel connection of a first coil and at least one second coil. At least two first loops of the first coil are configured for magnetic coupling. At least two second loops of the second coil are configured for magnetic coupling.

The aforementioned object is achieved further by the features of the monolithic integrated inductor according to claim 10. Advantageous refinements are the subject of dependent claims and sections of the description.

Accordingly, a monolithic integrated inductor is provided. The monolithic integrated inductor has a first coil with a first inductance value. The monolithic integrated inductor has at least one second coil with a second inductance value. The at least one second coil is connected parallel to the first coil. The parallel-connected coils form a total inductor.

Preferably, the coils of the monolithic integrated inductor are formed using planar technology. Preferably, the coils are formed in this case in one or more metallization levels of the integrated circuit. The first coil and the second coil are preferably arranged in such a way that each coil area encompassed by the coil windings is arranged parallel to the surface of the integrated circuit.

Lines are provided advantageously to the first coil and to the second coil. The first coil advantageously has at least two first loops, spaced at a distance, with a path width. The second coil advantageously has at least two second loops, spaced at the distance, with the path width. The first loops and the second loops each form a magnetic coupling.

A monolithic integrated inductor dependent on the desired resonant circuit frequency is needed particularly to achieve high resonant circuit frequencies of an integrated oscillator for a parallel resonant circuit or for a series resonant circuit at a specified settable capacitance and specified parasitic capacitances. Because of the high resonant circuit frequency, a very low inductance value of the monolithic integrated inductor is needed.

The parallel connection of the first coil with the first inductor and the second coil with the second inductor to form the total inductor makes it possible to provide the first coil and the second coil with a magnetic coupling to increase the quality of the first coil and the second coil. The increase in the quality of the first coil and the second coil also produces an increase in the total quality of the parallel connection by means of their parallel connection.

A monolithic integrated configuration of the first coil and the second coil using planar technology has the result that the coil paths of a coil are made preferably spaced from one another in the lateral direction (in regard to the chip surface). The coil paths can also be formed spaced in the vertical direction (in regard to the chip surface). If the coil paths are spaced solely in the vertical direction, however, parasitic capacitances are increased significantly and moreover are subject to greater process variations.

A parasitic capacitance, forming between the coil paths of a coil, therefore between the coil paths of the first coil or between the coil paths of the second coil, declines with an increasing distance of the coil paths from one another in the lateral direction. The coil area, encompassed by all turns, formed by the coil paths, of the particular coil, also declines with increasing distance.

To achieve an increase in quality under these boundary conditions, it is provided advantageously that the first coil and the second coil each have at least two loops (turns) which encompass a coil area and produce the magnetic coupling. Loops encompassing a coil area are meant to indicate that the coil area is encompassed by each loop of the coil at an angle greater than 300°. The loops encompassing the coil area can also be called complete loops.

To achieve an increase in quality, it is provided advantageously that the total inductor has a coil inductance and a line inductance of lines to the first coil and/or to the second coil, whereby the coil inductance is at least 20 times greater than the line inductance.

To achieve an increase in quality, it is provided advantageously that a coil distance between the first coil and the second coil is greater than the sum of a twofold path width of the coil paths and a path distance. This type of configuration of the coil geometry preferably produces a lower magnetic coupling of the first coil and the second coil to one another.

Preferably, the total inductor of the parallel-connected monolithic integrated coils is designed for an operating frequency. It is advantageous for the operating frequency to be settable within an adjustment frequency range. To set the operating frequency, for example, a connected capacitor or the total inductor can be configured as settable. Preferably, each coil resonance frequency of the two monolithic integrated coils is at least twice as large as the operating frequency. Preferably, each coil resonance frequency is twice as large as each sufferable operating frequency within the adjustment frequency range.

Preferably, the at least two monolithic integrated coils together with a monolithic integrated capacitive unit are used to form a resonant circuit. The capacitive unit can be connected in parallel or in series to the total inductor.

Preferably, a capacitor of the monolithic integrated capacitive unit is configured settable to set a resonant circuit frequency. In this case, the settable resonant circuit frequency corresponds to the operating frequency.

According to a preferred refinement, an integrated resonant circuit with the monolithic integrated inductor is provided, whereby the integrated resonant circuit has a monolithic integrated capacitive unit, which is connected parallel to the first coil and to the second coil and is arranged between the first coil and the second coil. Preferably, the first coil and the second coil are spaced from one another at least by a dimension of the monolithic integrated capacitive unit.

Preferably, the capacitive unit has at least one metal-insulator-metal capacitor, a varactor, a switched MIM capacitor, and/or a switched capacitor bank.

A preferred refinement provides that a first coil resonance frequency of the first coil is formed by adapting a first parasitic coil capacitor to a first coil inductor of the first coil by setting a path width and a distance of the first coil loops. Preferably, a second coil resonance frequency of the second coil is formed by adapting a second parasitic coil capacitor to the second coil inductor of the second loop by setting a path width and a distance of the second coil loops.

It is provided in an advantageous embodiment of this refinement that a first number of the first loops of the first coil is determined depending on the first coil resonance frequency and a particularly settable operating frequency. Preferably, a second number of the second loops of the second coil is determined depending on the second coil resonance frequency and the particularly settable operating frequency.

In an especially preferred refinement, it is provided that the gains caused by the magnetic coupling between the loops of a coil exceed the ohmic losses due to current displacement effects as a result of the proximity effect of the respectively neighboring loop, by defining a distance and a path width of the loop paths for this condition. Preferably, a difference of the gains and losses assumes a maximum value. The distance between neighboring loops and the path width of each loop are determined for this maximum value.

According to a preferred refinement, the magnetic coupling between the first conductor loops of the first coil exceeds a magnetic coil coupling between the first coil and the second coil. Likewise, in this refinement, the magnetic coupling between the second conductor loops of the second coil exceeds a magnetic coil coupling between the first coil and the second coil.

According to an especially advantageous embodiment, the path width and the distance are the same. The equality of the path width and distance is thereby to be understood as an equality achievable during the fabrication process with defined fabrication tolerances. Advantageously, the path width and the distance are produced with the same dimension of the exposure mask.

According to another embodiment, the value of the distance exceeds that of the path width to reduce, for example, active parasitic capacitances between neighboring loops. Advantageously, the value of the distance is smaller than the twofold value of the path width to achieve, for example, as sufficiently large coil area.

In a preferred embodiment, the first coil and the second coil are formed identical or symmetric to one another. For the symmetric configuration, the first coil and the second coil can be arranged to one another, for example, in a point symmetric or mirror symmetric manner.

It is advantageously provided in terms of configuration that the first and second inductance values have a minimum and a maximum inductance value. The minimum inductance value falls below the maximum inductance value by at most 20%, preferably by at most 10%.

An advantageous embodiment provides that a predefinable total inductance value with the parallel connection of the inductance values coincides substantially with the product of the number of the first and second coils and a predefinable total inductance value of the monolithic integrated inductor.

According to another aspect of the invention, a tunable oscillator with at least one previously described monolithic integrated inductor is provided. To tune the oscillator, said oscillator is advantageously configured as voltage-controlled or current-controlled.

According to yet another aspect of the invention, an integrated resonant circuit with at least one previously described monolithic integrated inductor is provided.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows an equivalent circuit for a coil,

FIG. 2 shows a diagram with a quantity for the impedance of coils of the conventional art,

FIG. 3 shows a diagram with coil qualities of coils of the conventional art,

FIG. 4 shows a schematic diagram with coil qualities of monolithic integrated coils,

FIG. 5 shows a schematic diagram of the inductance of a monolithic integrated coil depending on the number of turns,

FIG. 6 shows a schematic top plan view of a layout of two monolithic integrated coils,

FIG. 7 shows a schematic equivalent circuit of a tunable oscillator, and

FIG. 8 shows a block diagram of a WiMax transceiver having a circuit arrangement of the invention.

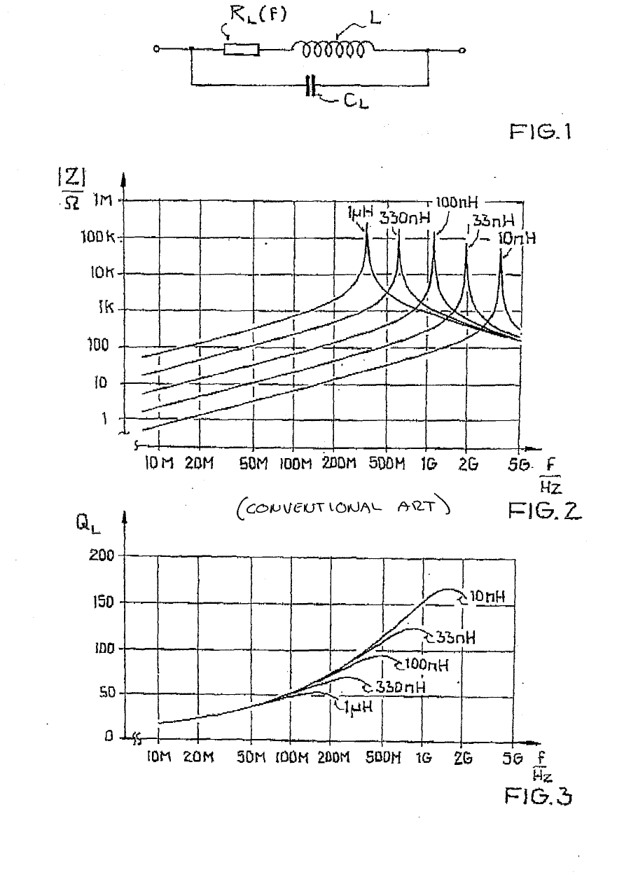

### DETAILED DESCRIPTION

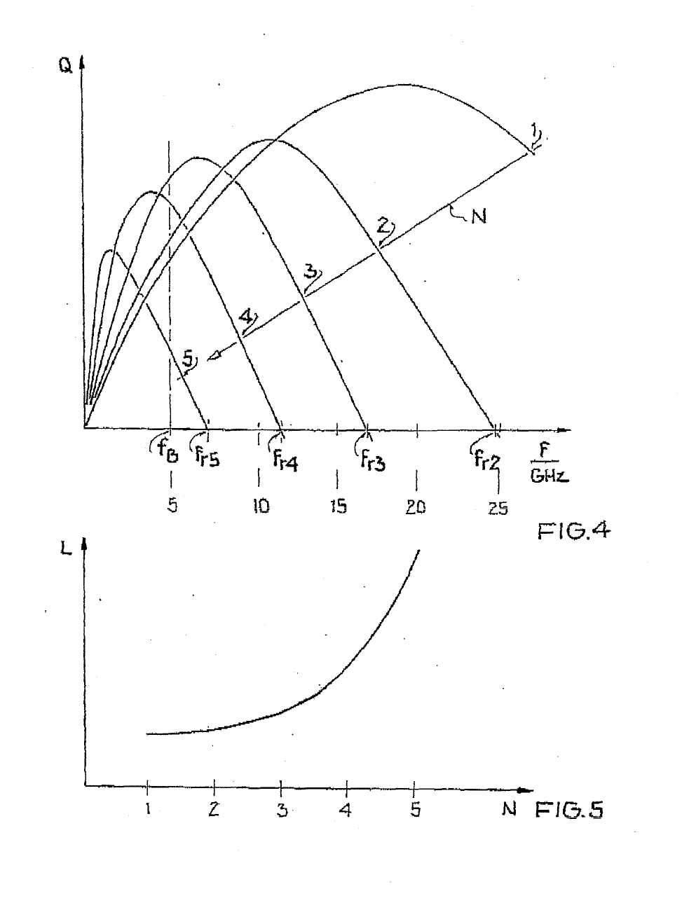

FIG. 4 shows a schematic diagram for a monolithic integrated inductor, where the quality Q of a monolithic integrated inductor is plotted on the ordinate and the frequency f on the abscissa. A set of curves is plotted for the different numbers N of loops 1, 2, 3, 4, and 5. The loops can also be called turns. The loops have a magnetic coupling to one another. For the turn number 2, 3, 4, and 5, moreover, the associated resonance frequency fᵣ₂, fᵣ₃, fᵣ₄, and fᵣ₅ is plotted on the abscissa. Furthermore, an operating frequency f_{B} is plotted and emphasized by a broken line.

It becomes clear from the schematic representation of the exemplary embodiments of FIG. 4 that with an increasing number N of loops of a coil, its coil resonance frequency fᵣ₂, fᵣ₃, fᵣ₄, fᵣ₅ declines. It is therefore required for the operating frequency f_{B} that the coil resonance frequency is at least twice as high as the operating frequency f_{B}. For very high operating frequencies, the coil with a single loop is therefore especially advantageous. If an operating frequency f_{B} that is much smaller than the coil resonance frequency for a single loop is required in the high-frequency spectrum, two or more loops with a magnetic coupling can be used to increase the quality Q.

Here, it is also necessary that the coil resonance frequency is at least twice as high as the operating frequency f_{B}. This applies only to the exemplary embodiments of FIG. 4 with the turn numbers 1, 2, 3, and 4. In contrast, the coil resonance frequency fᵣ₅ is not sufficiently high. For the operating frequency f_{B}, the quality Q increases from the turn number 1 up to turn number 3. Likewise for the turn number 4, the quality Q is increased compared with the turn number 1.

The quality Q of a loop has a specific R layer and a specific L layer:

$$Q = \frac{ω L}{R} \qquad ( 2 )$$

The following applies for two loops that are not magnetically coupled and connected in series:

$$Q = \frac{2 ω L}{2 R} \qquad ( 3 )$$

In this case, Q is the quality, ω the angular frequency, L the inductance of the two loops (without magnetic coupling), and R the ohmic resistance. For two loops with magnetic coupling ωM, the following applies in contrast:

$$Q = \frac{2 ω L + ω M}{2 R + {R}_{prox}} \qquad ( 4 )$$

In this case, Q is the quality, ω the angular frequency, L the inductance of the two loops (without magnetic coupling), R the ohmic resistance, ωM the magnetic coupling, and Rₚᵣₒₓ the losses due to current displacement (skin resistance).

The losses Rₚᵣₒₓ due to current displacement are small compared with the ohmic resistance R, when the distance of the coil paths deviates less than 20% from the path width of the coil path. In contrast, the gain due to the magnetic coupling ωM is significant and therefore leads to considerable improvement in the quality Q of the coil.

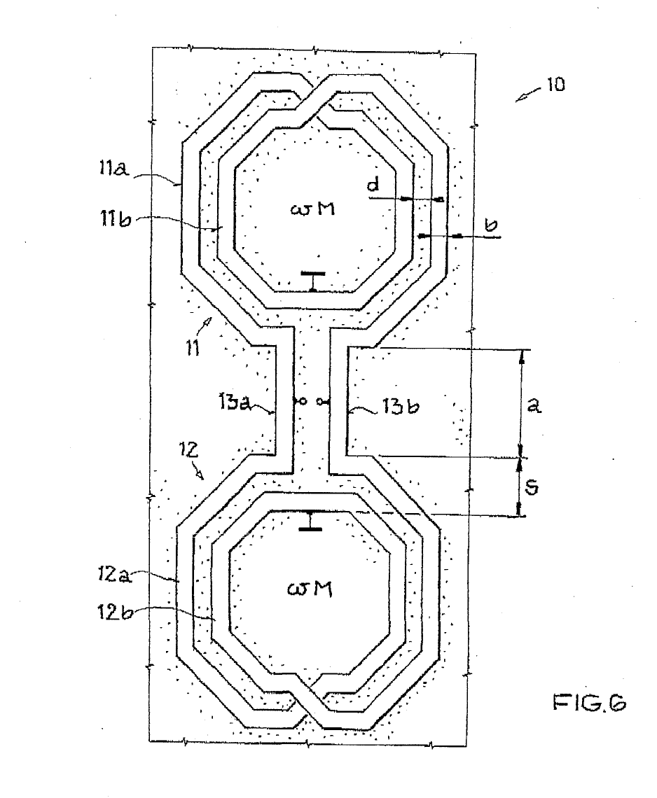

In FIG. 5, the increase of the inductance L with the loop number N of magnetically coupled loops is shown schematically as a diagram. Accordingly, the inductance L of magnetically coupled loops increases overproportionally, particularly quadratically, with an increase in the number N of loops.

An exemplary embodiment of a monolithic integrated inductor 10 is shown schematically in FIG. 6. FIG. 6 shows a schematic layout of a first coil 11, a second coil 12, and lines 13a, 13b to coils 11, 12. The first coil 11 and the second coil 12 are connected in parallel and connected to one another via lines 13a, 13b. The first coil 11 has two conductor loops 11a and 11b, which encompass a common coil area and thus effect a magnetic coupling ωM. The second coil 12 has two conductor loops 12a and 12b, which encompass a common coil area and thus effect a magnetic coupling ωM. The magnetic coupling ωM depends on the coil area encompassed by the two loops 11a, 11b or 12a, 12b, and thereby also depends on a path width b and a distance d between loops 11a, 11b or 12a, 12b of a coil 11, 12.

In the exemplary embodiment of FIG. 6, the inductance values of the first coil and the second coil are determined predominantly by an inductance part of loops 11a, 11b or 12a, 12b. In contrast, the inductance part of lines 13a, 13b is smaller by at least the factor 20 than the inductance part of the loops 11a, 11b or 12a, 12b.

The coil distance a is dimensioned so that the magnetic coupling between coils 11 and 12 is smaller, preferably substantially smaller, than the magnetic coupling between the respective loops 11a, 11b or 12a, 12b. For this purpose, the coil distance a is formed greater than the sum s of two path widths b and a path distance d.

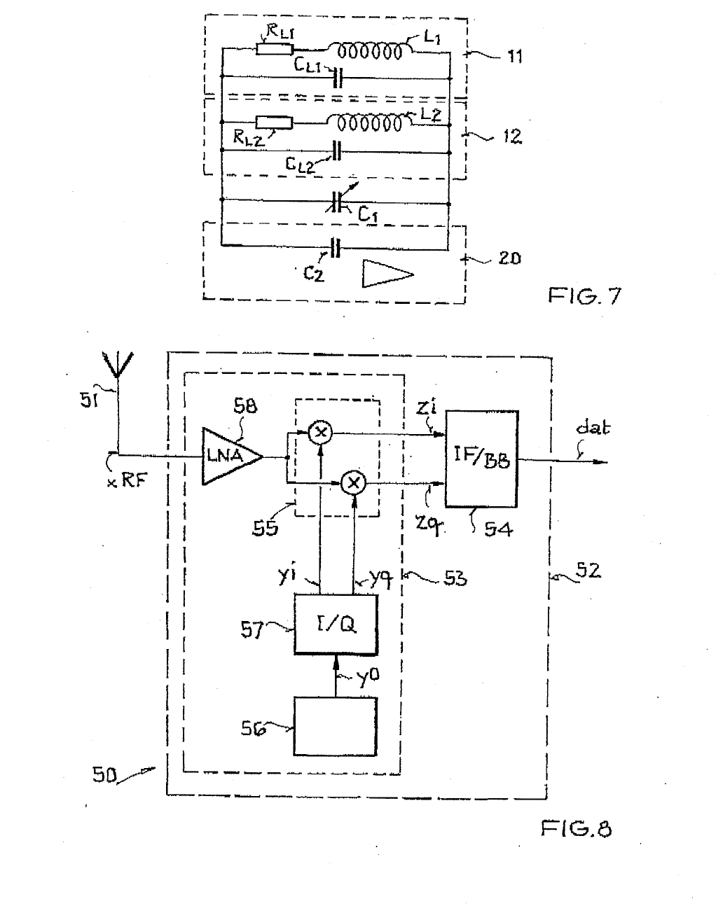

FIG. 7 shows a schematic equivalent circuit of a voltage-controlled oscillator, which has a first coil 11 and a second coil 12. The first coil 11 and the second coil 12 are connected in parallel. Furthermore, a capacitive unit C₁ and an amplifier element 20 with a parasitic capacitor C₂ are connected in parallel to first coil 11 and to second coil 12. Likewise, the parasitic capacitor C_{L1} of the first coil 11 and the parasitic capacitor C_{L2} of the second coil 12 are connected in parallel to capacitive unit C₁. A parallel resonance frequency thereby depends on the parallel connection of these capacitors C₁, C₂, C_{L1}, and C_{L2}. The total capacitance C is calculated to be

C=C₁+C₂+C_{L1}+C_{L2} (5)

The capacitance value of capacitive unit C1 is settable. Capacitive unit C1 therefore advantageously has at least one metal-insulator-metal capacitor, a varactor, a switched MIM capacitor, and/or a switched capacitor bank.

FIG. 8 shows a simplified block diagram of a transmitting/receiving device for a data transmission system according to IEEE 802.16 (WiMax, worldwide interoperability for microwave access).

Transmitting/receiving device 50 has an antenna 51 and a transmitting/receiving unit (transceiver) 52 connected to the antenna. Transmitting/receiving unit 52 comprises an HF front-end circuit 53, connected to antenna 51, and a downstream IF/BB signal processing unit 54. Transmitting/receiving unit 52 furthermore comprises a transmit path, which is not shown in FIG. 4 and is connected to antenna 51.

HF front-end circuit 53 amplifies a high-frequency radio signal xRF, which is received by antenna 51 and lies spectrally within the microwave range between 3.4 and 3.6 GHz, and converts (transforms) it into a quadrature signal z in an intermediate frequency range (intermediate frequency, IF) or in the baseband range (zero IF). The quadrature signal z is a complex-valued signal with an inphase component zi and a quadrature phase component zq.

The IF/BB signal processing unit 54 filters the quadrature signal z and shifts it perhaps spectrally into the baseband, demodulates the baseband signal, and detects the data dat contained therein and originally transmitted by another transmitting/receiving device.

The HF front-end circuit 53 has an amplifier (low noise amplifier, LNA) 58, connected to antenna 51, for amplifying the high-frequency radio signal xRF and a downstream quadrature mixer 55 for converting the amplified signal into the quadrature signal z. Furthermore, the HF front-end circuit 53 has a circuit arrangement 56 and a downstream I/Q generator 57, connected to quadrature mixer 55 on the output side. Circuit arrangement 56 has a controlled oscillator.

Circuit arrangement 56 advantageously has a voltage-controlled oscillator (VCO), whose frequency is set relatively roughly with the use of control voltages and fine tuned with the use of other (optionally PLL-controlled) control voltages. Circuit arrangement 56 is realized preferably according to the exemplary embodiment described previously with reference to FIGS. 6 and 7.

I/Q-Generator 57 derives from local oscillator signal y0 of circuit arrangement 56 a differential inphase signal yi and a differential quadrature phase signal yq phase-shifted by 90 degrees. Optionally, I/Q generator 57 comprises a frequency divider, amplifier elements, and/or a unit that assures that the phase offset of the signals yi and yq is 90 degrees as precisely as possible.

The HF front-end circuit 53 and thereby the at least one circuit arrangement 56 and perhaps parts of the IF/BB signal processing unit 54 are part of an integrated circuit (IC), which is formed, e.g., as a monolithic integrated circuit using standard technology, for example, a BiCMOS technology.

The monolithic integrated inductor described heretofore by exemplary embodiments can be used advantageously in highly diverse applications such as, e.g., in oscillator, amplifier, and filter circuits (settable transfer function, bandwidth, etc.).

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. Use of at least two monolithic integrated coils with a total inductance to increase quality, instead of a monolithic integrated single coil with the same inductance, the at least two monolithic integrated coils being connected in parallel, and each of the two monolithic integrated coils having at least two loops with a magnetic coupling between the two loops.

2. The use of at least two monolithic integrated coils according to claim 1 for a settable operating frequency, wherein each coil resonance frequency of the two monolithic integrated coils is at least twice as large as the particularly settable operating frequency.

3. The use of at least two monolithic integrated coils according to claim 1, further comprising a monolithic integrated capacitive unit for forming a resonant circuit.

4. The use of at least two monolithic integrated coils according to claim 3, wherein a capacitance of the monolithic integrated capacitive unit is settable, and wherein a settable resonant circuit frequency corresponds to the operating frequency.

5. A method for configuring a monolithic integrated inductor, the method comprising:
forming the inductor by a parallel connection of a first coil and at least one second coil;
configuring at least two first loops of the first coil for magnetic coupling; and
configuring at least two second loops of the second coil for magnetic coupling.

6. The method according to claim 5, wherein the first coil and the second coil are spaced from one another in such a way that a coil distance is greater than a sum of the twofold path width of the paths of the coil and a path distance.

7. The method according to claim 5, wherein a first coil resonance frequency of the first coil is formed by adapting a first parasitic coil capacitor to a first coil inductor of the first coil by setting a path width and a distance of the loop of the first coil, and a second coil resonance frequency of the second coil is formed by adapting a second parasitic coil capacitor to the second coil inductor of the second coil by setting a path width and a distance of the loops of the second coil.

8. The method according to claim 7, wherein a first number of the first loops of the first coil is determined depending on the first coil resonance frequency and a settable operating frequency, and wherein a second number of the second loops of the second coil is determined depending on the second coil resonance frequency and the settable operating frequency.

9. The method according to claim 5, wherein gains caused by the magnetic coupling between the loops exceed ohmic losses due to current displacement effects as a result of the proximity effect of the respectively neighboring loop by defining a distance and a path width of the loop paths.

10. A monolithic integrated inductor comprising:
a first coil having a first inductance value;
at least one second coil connected in parallel to the first coil and having a second inductance value to form a total inductance; and
lines to the first coil and to the second coil;
wherein the first coil has at least two first loops spaced at a distance with a path width,
wherein the second coil has at least two second loops spaced at the distance with the path width,
wherein the first loops form a magnetic coupling, and
wherein the second loops form a magnetic coupling.

11. The monolithic integrated inductor according to claim 10, wherein the gains caused by the magnetic coupling between the first and between the second loops exceed the ohmic losses due to the current displacement effects as a result of the proximity effect of the respectively neighboring loop particularly by the formation of the distance and the path width.

12. The monolithic integrated inductor according to claim 10, wherein a difference of the gains and losses assumes a maximum value.

13. The monolithic integrated inductor according to claim 10, wherein the magnetic coupling between the first conductor loops exceeds a magnetic coil coupling between the first coil and the second coil, and wherein the magnetic coupling between the second conductor loops exceeds a magnetic coil coupling between the first coil and the second coil.

14. The monolithic integrated inductor according to claim 10, wherein the path width and the distance are substantially the same.

15. The monolithic integrated inductor according to claim 10, wherein the value of the distance exceeds that of the path width.

16. The monolithic integrated inductor according to claim 10, wherein the value of the distance is smaller than a twofold value of the path width.

17. The monolithic integrated inductor according to claim 10, wherein the first coil and the second coil are formed substantially identical or symmetric to one another.

18. The monolithic integrated inductor according to claim 10, wherein the first and second inductance values have a minimum and maximum inductance value and the minimum inductance value falls below the maximum inductance value by at most 20%, preferably by at most 10%.

19. An integrated resonant circuit having a monolithic integrated inductor according to claim 10 and a monolithic integrated capacitive unit, which is connected in parallel to the first coil and to the second coil and is arranged between the first coil and the second coil.

20. The integrated resonant circuit according to claim 19, wherein the capacitive unit has at least one metal-insulator-metal capacitor, a varactor, a switched MIM capacitor, or a switched capacitor bank.

21. A tunable oscillator having at least one monolithic integrated inductor according to claim 10 and at least one integrated resonant circuit having a monolithic integrated capacitive unit, which is connected in parallel to the first coil and to the second coil and is arranged between the first coil and the second coil.
